(19) United States
(12) Patent Application Publication
(10) Pub. No.: US 2005/0150459 A1
(43) Pub. Date: Jul. 14, 2005

(54) Full glass substrate deposition in plasma enhanced chemical vapor deposition

(76) Inventors: Quanyuan Shang, Saratoga, CA (US); Robert I. Greene, Fremont, CA (US); Li Hou, Cupertino, CA (US)

Correspondence Address: MOSER, PATTERSON & SHERIDAN, LLP;APPLIED MATERIALS, INC., 3040 POST OAK BOULEVARD, SUITE 1500, HOUSTON, TX, 77056, US

(21) Appl. No.: 11/010,956

(22) Filed: Dec. 13, 2004

Related U.S. Application Data
(63) Continuation of application No. 10/024,985, filed on Dec. 18, 2001, now abandoned.
(60) Provisional application No. 60/259,027, filed on Dec. 29, 2000.

(51) Int. Cl. C23C 16/00

(52) U.S. Cl. 118/723 R; 427/248.1

(57) ABSTRACT

Embodiments of the invention generally provides an apparatus and a method for minimizing the deformation of a substrate during PECVD processing. In one aspect, the substrate is supported within a processing region on an insulating layer to provide uniform heating of the substrate.

### CROSS-REFERNCE TO RELATED APPLICATIONS

This application is a continuation of co-pending U.S. patent application Ser. No. 10/024,985, filed Dec. 18, 2001, which claims benefit of U.S. provisional patent application Ser. No. 60/259,027, filed Dec. 29, 2000. Each of the aforementioned related patent applications is herein incorporated by reference.

### BACKGROUND OF THE INVENTION

1. Field of the Invention

The invention generally relates to an apparatus and method for plasma enhanced chemical vapor deposition.

2. Background of the Related Art

In the fabrication of flat panel displays, transistors and liquid crystal cells, electronic devices, and other features are formed by depositing and removing multiple layers of conducting, semi-conducting and dielectric materials from a substrate. Glass substrate processing techniques include plasma-enhanced chemical vapor deposition (PECVD), physical vapor deposition (PVD), etching, other processes used to deposit material on a substrate. Plasma processing is particularly well-suited for the production of flat panel displays because of the relatively lower processing temperatures required to deposit a film and the good film quality which results from using plasma processes.

In general, plasma processing involves positioning a substrate on a support member, often referred to as a susceptor or heater, disposed in a vacuum chamber, and striking plasma adjacent to the upper exposed surface of the substrate. The plasma is formed by introducing one or more process gases into the chamber and exciting the gases with an electrical field to cause dissociation of the gases into charged and neutral particles. A plasma may be produced inductively, e.g., using an inductive RF coil, and/or capacitively, e.g., using parallel plate electrodes, or by using microwave energy. The disassociated gases react and form a film or layer on the substrate.

One issue with flat panel display processing is the detrimental effects of thermal dynamics on the panels, typically made of silica, fused silica, or quartz. During processing, the substrate is typically heated or cooled by the support member and is heated by the plasma. The support member is conventionally heated by one or more heating elements, such as resistive coils, or can be cooled by one or more fluid channels formed in the support member thereof. Uniform heating of the substrate is necessary to ensure uniform deposition. Where the thermal gradient across the substrate is not uniform, i.e., where the profile exhibits relative hot and cold spots, the deposition of material onto the substrate is non-uniform and results in defective devices. In addition, thermal gradients across the surface of a substrate can result in bowing or other deformation of the substrate, which can negatively affect the uniformity of deposition on the substrate.

Flat panel displays are particularly susceptible to the detrimental effects of thermal non-uniformity because the area of the substrate exposed to deposition is very large as compared to the substrate thickness and the thermal conductivity differences between the substrate and support member. In a typical deposition process, the substrate may be maintained at a temperature about 30-60° C. less than the temperature of the support member that may be heated to a temperature between about 250-450° C. As the substrate has thermal insulating properties, the surface of the substrate contacting the supporting member is typically heated to a different temperature than the surface of the substrate proximate the plasma. Further, the support member and the substrate surfaces nearest the heating element within the support member are heated to a greater temperature than the substrate surfaces nearest the plasma. Temperature differentials between the substrate surfaces caused by non-uniform heating generate thermal gradients within the substrate. Because of the substrate's low coefficient of expansion (i.e., rate of expansion when heated) and thermal conductivity (i.e., rate of heat absorption and transference), thermal gradients within the substrate cause substrate deformation such as warping and bowing, often referred to as the “potato chip” effect, resulting in a damaged and perhaps unusable substrate.

To cost effectively process non-deformed substrates requires protecting the substrate from substantial deformation while providing uniform deposition over as much substrate surface area as possible. Conventionally, a shadow frame or clamp ring has been used to hold the substrate on the support member and to prevent any deformation of the substrate. Unfortunately, the use of shadow frames or clamp rings minimizes the available deposition area on the substrate for formation of electronic devices, and hence is a limitation on the overall size and number of the devices. For example, a deposition-masking apparatus, or shadow frame, is placed over the periphery of the substrate to firmly hold the substrate on the support member during processing to eliminate substrate deformation. The shadow frame may be positioned in the processing chamber above the support member so that when the support member is moved into a raised processing position the shadow frame is picked up and contacts an edge portion of the substrate. The shadow frame generally comprises a lip or finger portion extending over the edge of the substrate. The lip or finger prevents a portion of the masked area of the substrate from receiving deposition, an effect known as edge exclusion. As a result, the shadow frame covers up to several millimeters of the periphery of the upper surface of the substrate, thereby preventing edge and backside deposition on the substrate. Moreover, in a processing position the shadow frame generally extends toward the chamber walls to prevent processing gases or plasma from leaking around the support member and draining energy from the plasma. Additionally, conventional shadow frames having the lip or finger portion leave a gap between the substrate and the support member to minimize the shadow frame contact with the substrate, thereby creating the potential for arcing between the substrate and the support member. Thus, while conventional shadow frames and clamp rings keep the substrate from being deformed and reduce deposition on the chamber walls, the usable area of the substrate is greatly reduced. Consequently, each processed substrate includes an unprocessed, unusable portion that reduces the usable surface area on a substrate and results in lower productivity of the processing system thereby increasing the cost of substrate manufacturing.

One exemplary shadow frame is found in U.S. Pat. No. 6,335,108, issued Mar. 12, 2002, entitled “Film Deposition Using a Finger Type Shadow Frame,” filed Jun. 11, 1999, herein incorporated by reference in its entirety.

Therefore, there is a need for an apparatus and method that eliminates substrate deformation, prevents arcing between the substrate and the support member, minimizes plasma loss within the chamber, and maximizes the available substrate deposition area.

### SUMMARY OF THE INVENTION

The invention generally provides a method and apparatus for depositing material on a substrate. The apparatus comprises a chamber having sidewalls, a bottom, a lid, a process gas distribution assembly coupled to the chamber, a power source coupled to the chamber for establishing a plasma, and a movable substrate support member disposed within the chamber having a support surface thereon and a thermally insulating layer disposed on the support surface to support a substrate thereon.

In another embodiment, the invention provides an apparatus for material deposition on a substrate, comprising a chamber, a process gas distribution assembly within the chamber, a power source coupled to the chamber for establishing a plasma, a movable substrate support member within the chamber having a support surface thereon and a thermally insulating layer on the support surface to support a substrate thereon, and a frame disposed on the thermally insulating layer. The frame when raised by the movable substrate support to a processing position is electrically insulated from the chamber.

In another embodiment, the invention provides a method for heating a substrate. The method comprises supporting a substrate on a thermally insulating surface within a chamber, heating a substrate support member, striking plasma, and then uniformly heating the substrate.

### BRIEF DESCRIPTION OF THE DRAWINGS

So that the manner in which the recited features of the invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 is a cross-sectional view of one embodiment of a processing chamber in accordance with the invention illustrating the chamber and chamber components.

FIG. 2 is a partial cross-sectional view of the chamber of FIG. 1.

FIG. 3 is a partial cross-sectional view of the chamber of FIG. 1 illustrating a substrate placed within the processing chamber.

FIG. 4 is a partial cross-sectional view of the chamber of FIG. 1 illustrating the movement of a support member toward the substrate.

FIG. 5 is a partial cross-sectional view of the chamber of FIG. 1 illustrating the substrate in a processing position.

### DETAILED DESCRIPTION OF THE PREFERRED EMBODIMENT

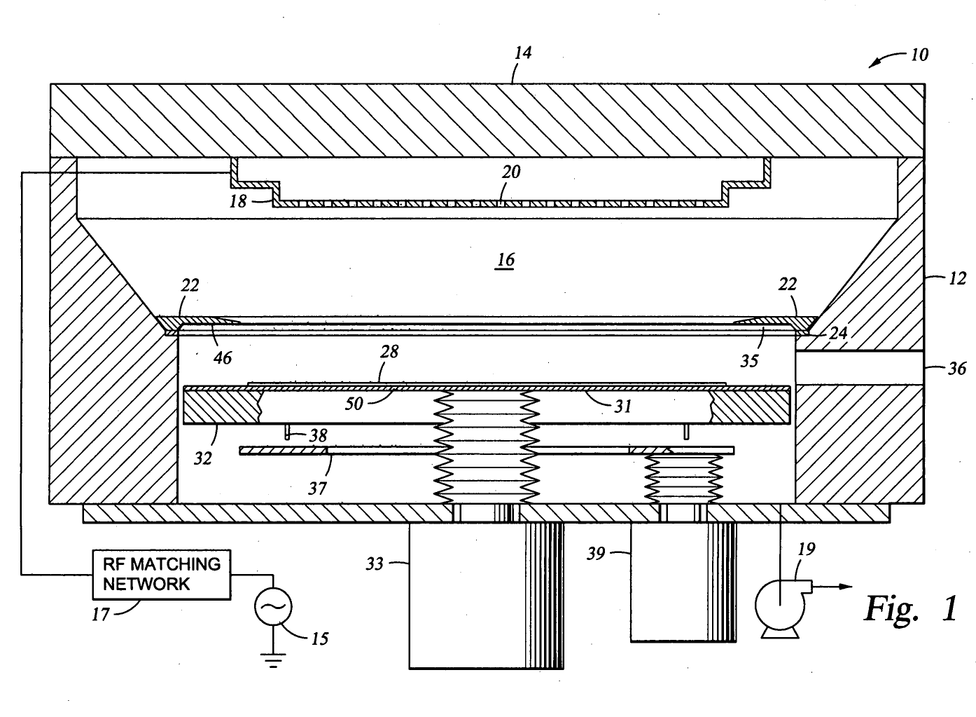

FIG. 1 is a cross-section of one embodiment of a processing chamber 10 of the invention adapted for processing substrates. The processing chamber 10 comprises a body 12 and a lid 14 disposed on the body 12. The processing chamber 10 defines a cavity that includes a processing region 16 therein. A gas dispersion plate (e.g., a showerhead) 18 is mounted to the lid 14 and defines the upper boundary of the processing region 16. A plurality of holes 20 are formed in the gas dispersion plate 18 to allow delivery of processing gases therethrough and into the chamber. Although, in one aspect the gas dispersion plate 18 also acts as an anode coupled to an RF generator 15 and matching network 17 to supply RF energy to the processing region 16, other anodes such as plates, electrodes, and antennas may be used to deliver the RF energy to the processing region 16. The chamber 10 also includes a movable substrate support member 32, also referred to as a susceptor, which can be raised or lowered in the chamber by a motor 33. The substrate support member 32 is typically heated using resistive heaters, lamps, or other heating devices commonly used in the field of electronic device fabrication. The heated substrate support member therefore includes a heater to heat a substrate 28. A vacuum pump 19 is coupled to the chamber 10 to control the chamber pressure therein.

A frame 22 comprised of a metallic material, such as aluminum, anodized aluminum, ceramic, and other similar materials, is shown disposed on a hanger 24 of the body 12. The frame 22 comprises alignment edges 35 and a protruding lower contact surface 46 extending longitudinally inward within the chamber 10 to define an inner opening, the inner diameter of which is slightly larger than, and conformal with, the substrate 28 being processed.

An insulating layer 50 is disposed on a support surface 31 of the support member 32 defining an upper substrate-supporting surface. The insulating layer 50 comprises insulating and/or semi-conducting materials such as ceramics, quartz, glass, and polymers adapted to thermally and electrically isolate the substrate 28 from the support member 32. Exemplary materials can include aluminum oxide, aluminum nitride, and other materials having thermally and electrically insulating properties. In one aspect, the insulating layer 50 comprises a single piece of material, such as aluminum oxide, which is disposed on and secured to the upper surface of the support member. Alternatively, several pieces or sheets of material can be bonded or otherwise adhered together to form a unified body. As one example, the insulating layer 50 may comprise a single sheet or several pieces bonded together on their ends to form a sheet, or several layers bonded together to form a puck. In another example, the insulating layer can be coated to the support surface 31 via direction coating of various kinds (e.g., anodization, plasma spray, thermal spray, sol-gel coating, etc.). Although, in one aspect the insulating layer 50 thickness be from about 1/8 inch to about 1/5 inch, other thicknesses are contemplated depending on the type of material used and the desired thermal properties. The thermal properties of the insulating layer 50 may be adapted to suite a particular substrate or process requirement. The thermal properties (i.e., thermal absorption and radiation) of the insulating layer are configurable by varying the material thickness, combining several layers of material, altering the material composition, and other methods adapted to alter the thermal properties. For example, a substrate or process step requiring a more rapid heating profile may use an insulating material that has a greater thermal conductivity, a thinner material of the same composition, or by forming a material composition to suit the requirement. The insulating layer 50 may be attached to the supporting member 32 using several methods. For example, in one aspect the insulating layer 50 may be attached to the support member 32 by the force exerted by its own weight on the support surface 31. Alternatively, the insulating layer 50 may be attached to the support surface 31 by the force exerted from the weight of the insulating layer 50 in cooperation with the weight of frame 22 when the support member 32 is raised to a processing position. When the insulating layer 50 is held in place by weight, the insulating layer 50 can be easily removed for cleaning or replacement without affecting the throughput of the processing system. The insulating layer 50 can then be cleaned and recycled for later use. In still another aspect, the insulating layer 50 is bonded to the support surface 31 using adhesives such as pressure sensitive adhesives, ceramic bonding, glue, and the like, or fasteners such as screws, bolts, clips, and the like. In still another aspect, the insulating layer 50 can be formed on the support surface 31 using techniques such as electroplating, sputtering, anodizing, plasma spray, Sol-Gel coating and the like. In still another aspect, the insulating layer 50 is integrally formed within the body of the support member 32 defining the support surface 31. Preferably, the insulating layer 50 is shaped to conform with and cover the support member 32.

The substrate 28 is introduced into the chamber 10 through an opening 36 formed in the body 12 that is selectively sealed by a slit valve mechanism (not shown). The substrate 28 is positioned and aligned on the insulating layer 50 by a robot blade. Lift pins 38 (four are shown) are slidably disposed through the support member 32 and insulating layer 50, and are adapted to hold the substrate 28 at an upper end thereof. The lift pins 38 are actuatable by an elevator plate 37 and an elevator motor 39 coupled thereto. While in one aspect four lift pins 38 are used to support the substrate 28, other numbers of lift pins are contemplated.

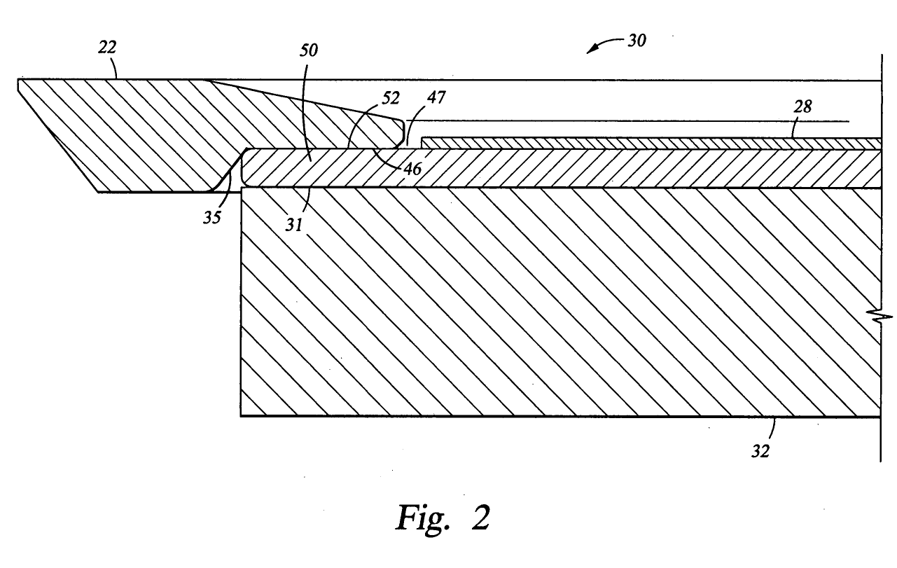

FIG. 2 is a partial cross-section of an assembly 30 showing one embodiment of the substrate support member 32 and insulating layer 50 raised to a processing position. Assembly 30 comprises the supporting member 32, the insulating layer 50, and the frame 22. The frame 22 extends the protruding lower contact surface 46 over an edge portion 52 of the insulating layer 50. The contact surface 46 and edge portion 52 define the portion of the frame 22 that maintains contact with the insulating layer 50 during processing. The insulating layer 50 provides support and electrical insulation for the frame 22 when the support member 32 is raised to a process position. In one aspect, the contact surface 46 may include rounded surfaces. The rounded surfaces are adapted to reduce possible damage such as abrasion, scratching, nicking, and the like to the insulating layer 50 due to mechanical and thermal stresses during processing, and to provide a substrate alignment surface. The substrate 28 fits within an opening defined by the protruding lower contact surface 46. A gap 47 is established between the frame 22 and the substrate 28 to allow for thermal expansion and placement of substrate 28 on the insulating layer 50.

As shown in the embodiment of FIG. 2, the frame 22 is supported by the insulating layer 50. The frame 22 provides clamping pressure on the edge portion 52 of the insulating layer 50 during processing, while maintaining an electrically insulated position relative to other chamber components such as the wall of the chamber 10. The downward force supplied by the weight of the frame 22 is localized to the contact between the surface 46 and the edge portion 52. Further, the substrate 28, insulating layer 50, and frame 22 define a plasma barrier within the gap 47 to keep the plasma from reaching the supporting member 32, thereby substantially eliminating arcing between the substrate 28 and the support member 32. As the frame 22 does not contact any portion of the substrate 28 during processing, no portion of the substrate 28 is obscured, maximizing the available deposition area. When raised to a process position on support member 32, the frame 22 extends substantially toward the chamber wall to provide an electrical insulation between the chamber wall and the plasma, generally preventing the plasma from leaking around the support member 32.

During the deposition process, thermal gradients within the chamber 10, process region 16, and substrate 28 result from internal thermal conductivities, thermal expansion, reflectivity of the various surfaces within the chamber 10, and proximity of components to heat sources such as plasma and the heated support member 32. Both the support member 32 and plasma heat the sides of the substrate 28 during processing. As the insulating layer 50 electrically and thermally insulates the substrate 28 from the heated supporting member 32, the substrate 28 is effectively “thermally floating” within the processing region 16, allowing the substrate 28 to be heated about uniformly from both sides. As the plasma is struck, heat is radiated from both the plasma, and the heated support member 32, to heat the substrate 28 from both sides. The insulating layer 50 provides a substrate-heating rate consistent with the substrate's heat absorption and radiation (i.e., thermal properties) allowing the heat throughout the substrate 28 to be substantially uniformly distributed and homogeneous. As the substrate 28 is heated uniformly, thermal expansion is also uniform and equally distributed within the substrate 28. Thus, the plasma and support member 32 heat the substrate 28 in cooperation with the insulating layer 50 to provide uniform heating and expansion throughout the substrate 28 thereby minimizing or eliminating thermal gradients. Additionally, the surface of dispersion plate 18 proximate the processing region 16 may be adapted to reflect the heat within the processing region 16 toward the support member 32 to help minimize and stabilize heat loss within the processing region 16, thereby improving substrate heating uniformity. The reflective surface of the dispersion plate 18 reflects heat to minimize heat losses through conduction. For example, the surface of the dispersion plate 18 may be coated with a mirrored surface such as polished aluminum, nickel, and the like, adapted to reflect heat. In a processing position, heat is reflected between the reflective surface, the insulating layer 50, heated support member 32, and frame 22, establishing a substantially homogeneous thermal profile within process region 16, thus providing a more consistent and uniform substrate heating. The uniformity of heating required is dependent on the physical and electrical characteristics of the substrate. Preferably, the heating uniformity should be such as to avoid substantial warping of the substrate that can make portions of the substrate unusable.

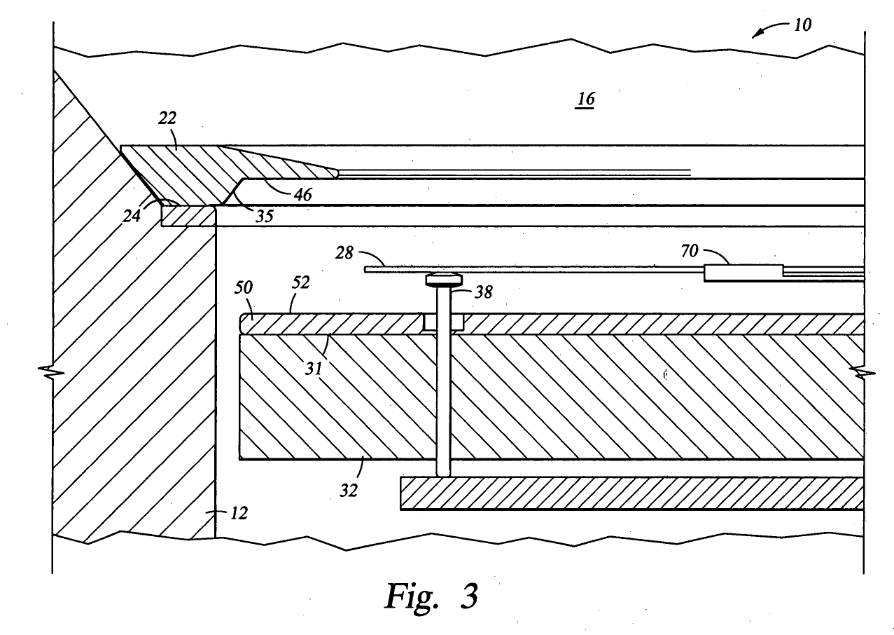

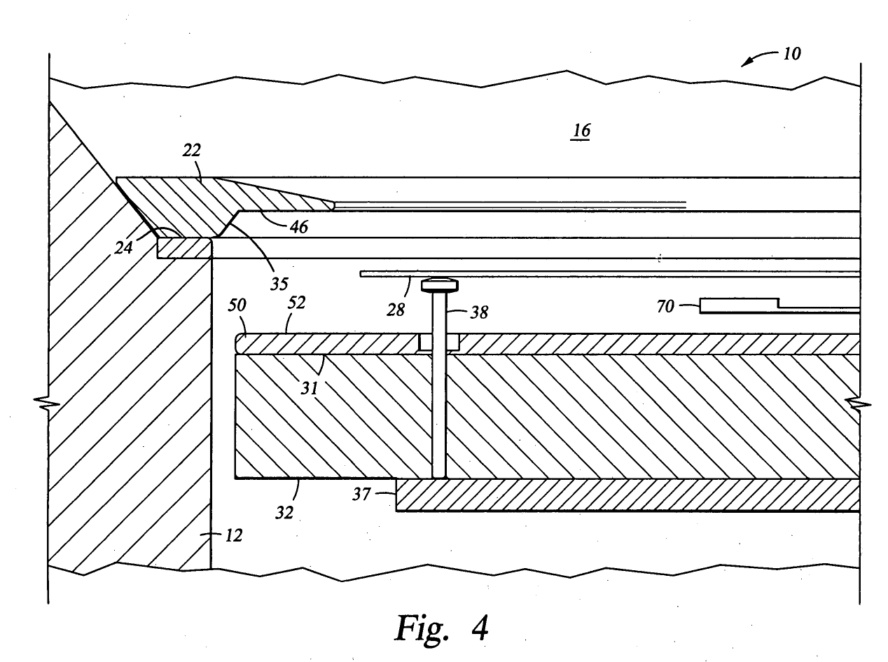

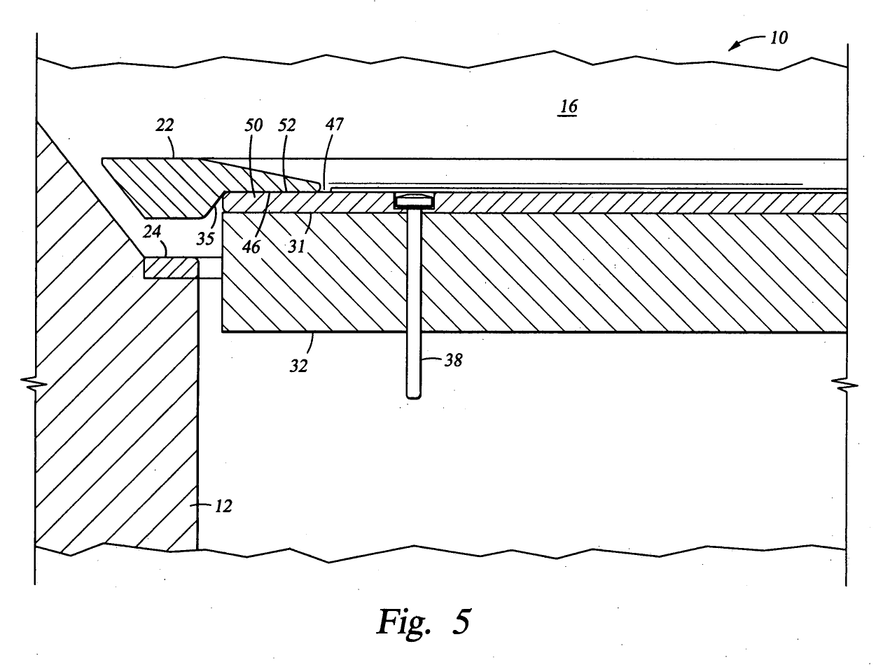

The operation of the assembly 30 is more fully understood with reference to FIGS. 3-5. Initially, a substrate 28 is introduced into the processing chamber 10 through an opening 36 (shown in FIG. 1) using a conventional robot blade 70, as shown in FIG. 3. The substrate 28 is supported on an upper surface of the robot blade 70 and is positioned above the raised lift pins 38. The support member 32 and lift pins 38 are actuated by motors 33 and 39 (shown in FIG. 1), respectively, to bring the lift pins 38 into contact with the substrate 28, thereby lifting the substrate 28 from the robot blade 70 as shown in FIGS. 3 and 4. The robot blade 70 is retracted and the support member 32 is raised relative to the stationary lift pins 38 as shown in FIG. 4. Subsequently, as the support member 32 continues to be raised, the periphery of the insulating layer 50 contacts angled alignment edges 35 of the frame 22. As the edge of the insulating layer 50 contacts the alignment edges 35, the frame 22 slides into alignment with the insulating layer 50. As the substrate 28 continues being raised into the processing position, the rounded edges of the frame 22 proximate the lower contact surface 46 and substrate 28 align the substrate 28 within the frame 22. When aligned, and disposed within the frame opening, the substrate 28 is substantially parallel to the surface 46 and the insulating layer 50 is in contact with the lower surface 46 of the frame 22. As the support member 32 continues to move into the processing position, the frame 22 is lifted from the hanger 24 as shown in FIG. 5. In the raised process position, the frame 22 is electrically isolated from the chamber plasma and therefore does not drain the plasma constituents, thus allowing a more uniform deposition process.

The deposition process is initiated by introducing one or more process gases (e.g., SiH₄, TEOS, NH₃, H₂, N₂, N₂O, PH₃, and the like) into the chamber 10 via the gas distribution plate 18 and are kept under a chamber pressure of about 0.2 to about 10 Torr by the vacuum pump 19. The gases are excited into a plasma state by supplying an electric field to the processing region 16 often using the RF generator 15 and matching network 17 coupled through the anode, i.e., the gas dispersion plate 18, thereby forming radicals of a deposition gas which will form a thin film (e.g., a-Si, SiN, SiO2, SiON, and the like) on the substrate 28. The RF power applied is about 100 watts to about 10,000 watts depending upon size of the chamber 10. To help provide uniform plasma coverage above the substrate 28, the gas dispersion plate 18 (i.e., the anode) is spaced between about 400 mils to 1500 mils above the support member 32. The plasma is generally maintained over the entire upper surface of the substrate 28 to ensure uniform deposition and a maximum usable surface area on the substrate 28. The substrate process temperature is maintained at about 150° C. to 450° C. In one aspect, during the processing, the substrate 28 maintains a temperature differential of less than about 20° C. relative to the temperature of the support member 32.

### EXAMPLE 1

In one process, an about 600 mm×720 mm substrate 28 was positioned on a support member 32 having an insulating layer 50 disposed thereon. The insulating layer 50 is formed of aluminum oxide and is between about 125 mils and about 500 mils thick. The insulating layer 50 is positioned on the support member 32 and held in place under its own weight. The substrate 28 is positioned on the insulating layer 50 and the support member 32 is moved into a processing position where an edge of the frame 22 is supported on the perimeter of the insulating layer 50 outwardly of the edge of the substrate exposing the entire substrate 28. SiH₄ is introduced at a flow rate of between about 260 sccm and 720 sccm, NH₃ is introduced at a flow rate of between about 900 sccm and 4000 sccm, and N₂ is introduced into the chamber 10 at a flow rate of between about 5000 sccm and 20000 sccm through the gas dispersion plate 18. The chamber power level is set to between about 200 watts and about 2900 watts. The chamber is maintained at a pressure of between about 1.0 Torr and about 3.0 Torr by the vacuum pump 19. The spacing between the anode (i.e., gas dispersion plate 18) and the substrate 28 is about 400 mils to about 1500 mils. The process temperature of the substrate 28 is between about 200° C. and about 450° C. A SiN film was deposited on the substrate 28 at a deposition rate of about 500 to about 3000 angstroms/minute.

### EXAMPLE 2

In another process, an about 600 mm×720 mm substrate 28 was positioned on a support member 32 having an insulating layer 50 disposed thereon. The insulating layer 50 is formed of aluminum oxide and is between about 125 mils and about 500 mils thick. The insulating layer 50 is positioned on the support member 32 and held in place under its own weight. The substrate 28 is positioned on the insulating layer 50 and the support member 32 is moved into a processing position where an edge of the frame 22 is supported on the perimeter of the insulating layer 50 outwardly of the edge of the substrate 28 exposing the entire substrate 28. SiH₄ is introduced at a flow rate of between about 100 sccm and 800 sccm, and H₂ is introduced into the chamber 10 at a flow rate of between about 1000 sccm and 5000 sccm through the gas dispersion plate 18. The chamber power level is set to between about 200 watts and about 1000 watts. The chamber 10 is maintained at a pressure of between about 1 Torr and about 5 Torr by the vacuum pump 19. The spacing between the anode (i.e., gas dispersion plate 18) and the substrate 28 is about 400 mils and about 1500 mils. The process temperature of the substrate 28 is about between 200° C. and about 450° C. An a-Si film was deposited on the substrate 28 at a deposition rate of about 200 to about 1000 angstroms/minute.

### EXAMPLE 3

In another process, an about 600 mm×720 mm substrate 28 was positioned on a support member 32 having an insulating layer 50 disposed thereon. The insulating layer 50 is formed of aluminum oxide and is between about 125 mils and about 500 mils thick. The insulating layer 50 is positioned on the support member 32 and held in place under its own weight. The substrate 28 is positioned on the insulating layer 50 and the support member 32 is moved into a processing position where an edge frame 22 is supported on the perimeter of the insulating layer 50 outwardly of the edge of the substrate 28 exposing the entire substrate 28. SiH₄ is introduced at a flow rate of between about 100 sccm and 500 sccm, and N₂O is introduced into the chamber at a flow rate of between about 5000 sccm and 15000 sccm through the gas dispersion plate 18. The chamber power level is set to between about 1000 watts and about 4000 watts. The chamber is maintained at a pressure of between about 0.5 Torr and about 3.0 Torr by the vacuum pump 19. The spacing between the anode (i.e., gas dispersion plate 18) and the substrate 28 is about 400 mils to about 1500 mils. The process temperature of the substrate 28 is between about 200° C. and about 450° C. A SiO film was deposited on the substrate 28 at a deposition rate of about 500 to about 3000 angstroms/minute.

While the foregoing is directed to the preferred embodiment of the present invention, other and further embodiments of the invention may be devised without departing from the basic scope thereof, and the scope thereof is determined by the claims that follow.

1. A method for heating a substrate, comprising:
supporting a substrate on a thermally insulating layer supported on a substrate support member within a chamber;
heating the substrate support member;
striking a plasma; and
uniformly heating the substrate.

2. The method of claim 1, heating the substrate comprises reflecting heat from a reflective surface toward the support member.

3. The method of claim 1, wherein the thermally insulating surface is adapted to uniformly maintain a differential temperature between the substrate and support member of less than about 20° C.

4. The method of claim 1, wherein prior to supporting, providing the thermally insulating surface on the support member.

5. The method of claim 1, wherein the thermally insulating surface is bonded to the support member.

6. The method of claim 1, wherein the thermally insulating surface is held on the support member by a frame member.

7. The method of claim 1, wherein the thermally insulating surface is selected from the group of insulators, semi-conductors, and combinations thereof.

8. The method of claim 7, wherein the thermally insulating surface is selected from the group of ceramic, glass, polymer, and combinations thereof.

9. The method of claim 1, wherein uniformly heating the substrate comprises:
heating both sides of the substrate using a first heating member to apply heat to a first substrate side and a second heating member to apply heat to a second substrate side, wherein the rate of heating between the first and second sides is substantially the same.

10. The method of claim 9, wherein the first heating member is a heated support member.

11. The method of claim 9, wherein the second heating member is a plasma.

12. The method of claim 9, further comprising heating the substrate to between about 150° C. to about 450° C.

13. The method of claim 1, wherein striking a plasma further comprises supplying a process gas within the chamber.

14. The method of claim 13, wherein the process gas is selected from the group of SiH₄, TEOS, NH₃, H₂, N₂, N₂O, PH₃, and combinations thereof.

15. The method of claim 13, wherein striking a plasma further comprises the step of supplying an RF power source of between about 100 watts and about 10,000 watts.

16. The method of claim 15, wherein the RF power is supplied through an anode having a spacing of between about 400 mils to about 1500 mils above the support member

17. An apparatus for material deposition on a substrate, comprising:
a chamber;
a process gas distribution assembly within the chamber;
a power source coupled to the chamber for establishing a plasma; and
a movable substrate support member within the chamber having a support surface thereon and a thermally insulating layer on the support surface to support a substrate thereon.

18. The apparatus of claim 17, wherein the substrate support member comprises a heater.

19. An apparatus for material deposition on a substrate, comprising:
a chamber;
a process gas distribution assembly within the chamber;
a power source coupled to the chamber for establishing a plasma;
a movable substrate support member within the chamber having a support surface thereon and a thermally insulating layer on the support surface to support a substrate thereon; and
a frame disposed on the thermally insulating layer that when raised by the movable substrate support to a processing position is electrically insulated from the chamber.

20. The apparatus of claim 19, wherein the substrate support member comprises a heater.
